(19) United States
(12) Patent Application Publication
(10) Pub. No.: US 2005/0085089 A1
(43) Pub. Date: Apr. 21, 2005

(54) Etching apparatus, semiconductor devices and methods of fabricating semiconductor devices

(76) Inventor: Jung Ho Kang, Bucheon-city (KR)

Correspondence Address: GROSSMAN & FLIGHT LLC, Suite 4220, 20 North Wacker Drive, Chicago, IL, 60606-6357, US

(21) Appl. No.: 10/956,607

(22) Filed: Sep. 30, 2004

(30) Foreign Application Priority Data
Oct. 1, 2003 (KR) 10-2003-0068488

(51) Int. Cl. H01L 21/302; H01L 21/20; H01L 21/76; H01L 29/00

(52) U.S. Cl. 438/713; 438/719; 438/716; 438/424; 257/521; 257/510

(57) ABSTRACT

Etching apparatus, semiconductor devices and methods for fabricating semiconductor devices are disclosed. An example semiconductor device comprises: a semiconductor substrate; and a trench formed in the semiconductor substrate for isolating the semiconductor device. The trench has an opening width which is narrower than any other part of the trench.

### FIELD OF THE DISCLOSURE

The present disclosure relates generally to semiconductor fabrication, and, more particularly, to etching apparatus, semiconductor devices and methods for fabricating semiconductor devices.

### BACKGROUND

A shallow trench isolation (STI) structure is often utilized as a semiconductor device isolation structure. The shallow trench isolation structure is advantageous in miniaturizing a semiconductor device because it limits the size of the field region. The STI structure is formed by making a trench in the semiconductor substrate and then filling the trench with dielectric material.

Conventional trench isolation structures are described in U.S. Pat. Nos. 5,843,226, 6,274,457, and 6,432,832.

FIG. 1a is a schematic view illustrating a conventional trench etching process. FIG. 1b is an enlarged cross-sectional view illustrating a conventional trench structure formed through the trench etching process of FIG. 1a. In the conventional trench formation process shown in FIG. 1a, a shower head 300 projects etching gas in a vertical direction relative to a surface of the semiconductor substrate 200. Accordingly, the semiconductor substrate 200 is etched in the vertical direction, and a trench (T) is formed in the semiconductor substrate as shown in FIG. 1b. During this process, the semiconductor substrate 200 is fixedly supported by a chuck 100.

In this conventional process, the etching speed in the horizontal direction (i.e., the etching of the inner sidewalls of the trench) is very slow relative to the etching speed in the vertical direction. Furthermore, the etching speed of the inner side wall is slower as one proceeds deeper into the trench. In other words, the lower part of the side wall of the trench experiences a slower etching speed then the upper part of the side wall of the trench. As a result, the trench structure formed through the conventional method has a cross-sectional profile wherein the width of the trench opening is wider than the width of the bottom of the trench as shown in FIG. 1b.

FIG. 2 is a cross-sectional view showing a semiconductor device employing conventional trench isolation structures 20. As shown in FIG. 2, the openings of the conventional STIs 20 are large relative to the bottoms of the trenches 20.

More specifically, in FIG. 2, a trench 20 having an opening which is larger than its bottom is formed in the semiconductor substrate 10. An individual device such as MOS transistor 30 is formed in the active region defined by the trenches 20. An interlayer dielectric layer 45 is formed on the semiconductor substrate 10 and the MOS transistor 30. Source/drain regions of the MOS transistor 30 are connected to metal wirings 50 through contact holes 40.

As shown in FIG. 2, there is little margin between the contact hole 40 active region and the trench 20 at the interface of the semiconductor substrate 10 and the interlayer dielectric layer 45. Consequently, the contact hole 40 and the trenches 20 are likely to be overlapped if the trenches 20 are mis-aligned. Such mis-arranged trenches thus cause leakage current with respect to the contact hole.

### BRIEF DESCRIPTION OF THE DRAWINGS

FIG. 1a is a schematic view of a conventional trench etching process.

FIG. 1b is an enlarged cross-sectional view illustrating a conventional trench formed through the trench etching process of FIG. 1a.

FIG. 2 is a cross-sectional view showing a semiconductor device incorporating the conventional trench isolation structure of FIG. 1b.

FIG. 3a is a schematic view of an example etching process performed in accordance with the teachings of the present invention.

FIG. 3b is a cross-sectional view of an example trench structure formed by the etching process of FIG. 3a.

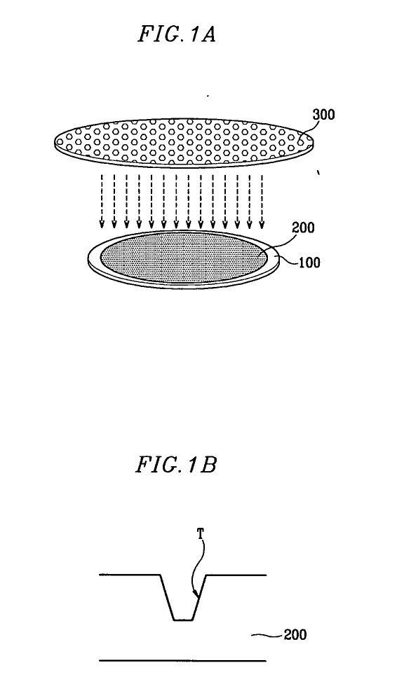

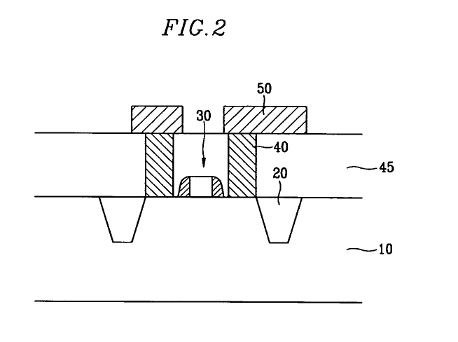

### DETAILED DESCRIPTION

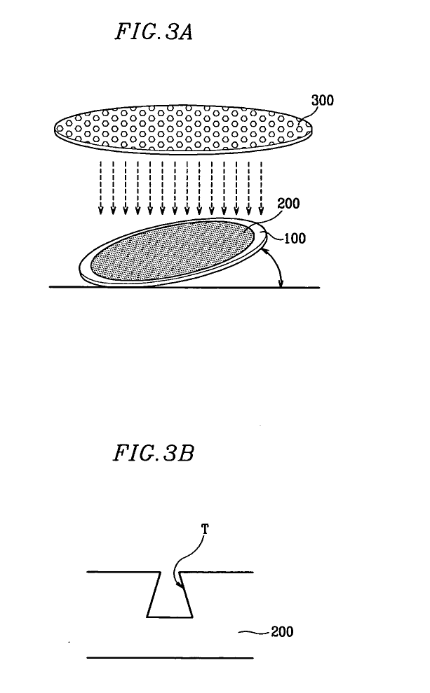

FIG. 3a is a schematic view of an example etching process performed in accordance with the teachings of the present invention to form a trench to isolate active regions of the semiconductor device. FIG. 3b is a cross-sectional view illustrating an example trench formed through the etching process of FIG. 3a. As shown in FIG. 3a, the example etching process is performed while the etching gas is injected from a shower head 300 such that the etching gas impinges the surface of the semiconductor substrate 200 at an angle. In other words, the shower head 300 and the surface of the substrate 200 are not parallel. In the illustrated example, the etching gas impinges on the surface of the substrate 200 at an angle that is not 90 degrees.

For the purpose of positioning the shower head 300 and the substrate 200 such that they are not parallel, the etching apparatus is provided with a slanted chuck 100 to support the semiconductor substrate 200 at an angle relative a horizontal plane. By etching the semiconductor substrate 200 at a slant, the etching is actively applied to an inner sidewall of the trench being formed. As a result, the etched amount is larger at the bottom of the trench.

By rotating the etch equipment or the semiconductor substrate 200 while the semiconductor substrate 200 is slanted, the sidewalls of the bottom of the trench are etched more than the opening of the trench. The chuck 100 is preferably rotated by a motorized drive to provide the relative rotation between the etch equipment and the substrate 200.

To form a linear trench line, the etching process is first performed while the etching direction is maintained at a first angle greater than 90 degree relative to the surface of the semiconductor substrate 200 so as to form a first slanted sidewall. The etching process is then performed while the etching direction is maintained at a second angle less than 90 degree relative to the same location on the surface of the semiconductor substrate 200 so as to form a second slanted sidewall opposite to the first slanted sidewall. Preferably, the first and second angles are equal, but opposite angles.

The etching gas is selected to suit the material of the semiconductor substrate 200. The etching gas is typically one of, or a mixture of at least two of: BCl₃, Cl₂, HBr, NF₃, O₂, SiF₄, and CF₃Br. However, other etching gases or mixtures of etching gases may alternatively be used.

An example trench T constructed via one of the above described processes has an opening which is narrower than its bottom as shown in FIG. 3B.

The trench T is preferably maintained in a vacuum or filled by dielectric material so as to isolate the device. The dielectric material filling the trench T can be carbide, oxide, nitride, oxynitride, or the like. However, persons of ordinary skill in the art will appreciate that the dielectric material is not limited to those materials, but rather any material which has dielectric characteristics and can fill the trench T may be employed. Materials having a flow characteristic such as silica glass facilitate filling the trench without voids, even though the trench opening is narrower than the bottom of the trench T.

By forming the trench T such that the opening is narrower than the bottom, the active region of a semiconductor device employing the trench can be very well isolated. Moreover, because the width of the trench opening is smaller than in prior art trenches, the margin for the contact hole arrangement is increased. In other words, by performing the etching process while the semiconductor substrate 200 is slanted at a predetermined angle relative to the etching gas stream, the trench T is formed such that its opening is narrower than its bottom and the margin for the contact hole arrangement is, thus, increased.

From the foregoing, persons of ordinary skill in the art will readily appreciate that a new trench structure which is capable of improving arrangement margins between the contact holes and trenches has been provided. Further, semiconductor devices which include a trench T formed in a semiconductor substrate 200 for isolating the semiconductor device, wherein the trench T has an opening which is narrower than any other part of the trench T have been disclosed. Preferably, the width of the trench T becomes monotonically narrower from the bottom of the trench T to the opening of the trench T as shown in FIG. 3B. Preferably, the trench T is maintained substantially in a state of vacuum, or filled with a dielectric material such as any of carbide, oxide, nitride, and oxynitride.

An example method for fabricating a semiconductor device comprises: forming a trench having a an opening with a narrower width than a bottom width by etching a semiconductor substrate while rotating the semiconductor substrate with an etching direction at an angle other than 90 degree relative to a surface of the semiconductor substrate by slanting either or both of the semiconductor substrate and the etching equipment.

In another example method, the trench T is formed so as to have the desired profile (e.g., an opening width which is narrower than a bottom width) by first etching a semiconductor substrate in a first etching direction at a first angle different than 90 degree relative to a surface of the semiconductor substrate, and then etching the substrate in a second etching direction at a second angle different than 90 degree relative to the surface of the semiconductor substrate. The first and second angles are opposite and may be substantially equal to form a uniform trench.

Preferably, the etching process is performed using one or more of: BCl₃, Cl₂, HBr, NF₃, O₂, SiF₄, and CF₃Br, as the etching gas.

Preferably, the etching apparatus includes a chuck to support the semiconductor substrate 200 at a slant. The chuck may be coupled to a drive to rotate the semiconductor substrate 200.

It is noted that this patent claims priority from Korean Patent Application Serial Number 10-2003-0068488, which was filed on Oct. 1, 2003, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A semiconductor device comprising:
a semiconductor substrate;
a trench formed in the semiconductor substrate for isolating the semiconductor device, the trench having an opening width which is narrower than any other part of the trench.

2. A semiconductor device as defined in claim 1, wherein a width of the trench becomes narrower going from a bottom of the trench to the opening.

3. A semiconductor device as defined in claim 1, wherein a width of the trench becomes monotonically narrower going from a bottom of the trench to the opening.

4. A semiconductor device as defined in claim 1, wherein the trench is substantially maintained in a vacuum.

5. A semiconductor device as defined in claim 1, wherein the trench is filled with a dielectric material.

6. A semiconductor device as defined in claim 5, wherein the dielectric material comprises carbide, oxide, nitride, or oxynitride.

7. A method for fabricating a semiconductor device comprising:
etching a semiconductor substrate at an etching direction that is not perpendicular to a surface of the semiconductor substrate; and
rotating the semiconductor substrate while etching the semiconductor substrate to form a trench having an opening width which is narrower than a bottom width.

8. A method as defined in claim 7, wherein the semiconductor substrate is slanted.

9. A method as defined in claim 7, wherein an etching device is slanted.

10. A method as defined in claim 7, wherein the etching process is performed using at least one of BCl₃, Cl₂, HBr, NF₃, O₂, SiF₄, or CF₃Br, as etching gas.

11. A method for fabricating a semiconductor device comprising:
etching a semiconductor substrate using a first etching direction that is not perpendicular to a surface of the semiconductor substrate; and
etching the semiconductor substrate using a second etching direction that is not perpendicular to a surface of the semiconductor substrate to form a trench having an opening width which is narrower than a bottom width

12. A method as defined in claim 11, wherein the first etching direction is substantially equal to but opposite the second etching direction.

13. An etching apparatus comprising:
a chuck to support a semiconductor substrate at an angle; and
a drive to rotate the chuck.
